(19) United States
(12) Patent Application Publication
(10) Pub. No.: US 2014/0159506 A1
(43) Pub. Date: Jun. 12, 2014

(54) POWER CONVERSION APPARATUS INCLUDING MULTIPLE DC-DC CONVERTERS AND METHOD OF CONTROLLING MULTIPLE DC-DC CONVERTERS

(71) Applicant: Samsung Electronics Co., Ltd., Suwon-si (KR)

(72) Inventors: Young-jae KIM, Seoul (KR); Hye-jung CHO, Anyang-si (KR); Jin-ho KIM, Yongin-si (KR); Dong-kwan KIM, Hwaseong-si (KR)

(73) Assignee: Samsung Electronics Co., Ltd., Suwon-si (KR)

(21) Appl. No.: 14/103,880

(22) Filed: Dec. 12, 2013

(30) Foreign Application Priority Data
Dec. 12, 2012 (KR) 10-2012-0144802

(51) Int. Cl. H03K 17/00

(52) U.S. Cl. CPC H03K 17/007
USPC 307/126; 307/116; 307/131

(57) ABSTRACT

A power conversion apparatus includes a plurality of converters which independently converts a voltage of power output from a power source, a measuring instrument which measures at least one predetermined characteristic value of power to be supplied from the power source to a load, and a controller for enabling or disabling each of the plurality of converters based on the at least one predetermined characteristic value.

### CROSS-REFERENCE TO RELATED APPLICATIONS

This application claims priority to Korean Patent Application No. 10-2012-0144802, filed on Dec. 12, 2012, and all the benefits accruing therefrom under 35 U.S.C. §119, the disclosure of which is incorporated herein in its entirety by reference.

### BACKGROUND

1. Field

The present invention relates to apparatuses for converting power output from a power source.

2. Description of the Related Art

Alternative energy sources such as fuel cells, solar cells and the like have been highlighted as environment-friendly technology by which air pollution may be effectively reduced. To supply power output from power sources, such as fuel cells, solar cells and the like, to loads, such as homes, vehicles, electronic devices and the like, a process of converting the power output from the power sources to a voltage suitable for individual loads is used. Accordingly, researches on power converters for efficiently converting power output from a power source have been conducted.

### SUMMARY

Provided are apparatuses and methods capable of implementing a compact direct current to direct current (“DC-DC”) converter of which power conversion efficiency is maximized throughout all load range.

Provided are non-transitory computer-readable storage media having stored therein program instructions, which when executed by a computer, perform the methods.

Additional embodiments will be set forth in part in the description which follows and, in part, will be apparent from the description, or may be learned by practice of the presented embodiments.

According to an embodiment of the present invention, a power conversion apparatus includes a plurality of converters which independently converts a voltage of power output from a power source, a measuring instrument which measures at least one predetermined characteristic value of power to be supplied from the power source to a load, and a controller for enabling or disabling each of the plurality of converters based on the at least one predetermined characteristic value.

In an embodiment, the controller may enable at least one converter, which corresponds to a number proportional to a magnitude of the at least one predetermined characteristic value of the power to be supplied to the load, from among the plurality of converters.

In an embodiment, the controller may enable at least one converter, which corresponds to a number proportional to a magnitude of any one predetermined characteristic value of the power to be supplied to the load, from among the plurality of converters. The any one predetermined characteristic value may be a current value of the power to be supplied to the load, and the controller may enable or disable each of the plurality of converters based on a magnitude of the current value.

In an embodiment, the controller may enable at least one converter, which corresponds to a number proportional to a magnitude of a value calculated from a plurality of predetermined characteristic values of the power to be supplied to the load, from among the plurality of converters. The plurality of predetermined characteristic values may be a voltage value of the power to be supplied to the load and a current value of the power to be supplied to the load, and the controller may enable at least one converter, which corresponds to a number proportional to a magnitude of a product of the voltage value and the current value, from among the plurality of converters.

In an embodiment, the controller may enable at least one of the plurality of converters based on the at least one predetermined characteristic value and control an operation of an enabled converter based on a current value of the power output from the power source so that a constant current is output from the power source. The controller may enable multiple converters of the plurality of converters based on the at least one predetermined characteristic value and control operations of the multiple converters so that the enabled multiple converters are sequentially switched.

In an embodiment, the power conversion apparatus may further include at least one group including a plurality of other converters different from a group including the plurality of converters, where the controller enables or disables the converter groups on a group basis based on the at least one predetermined characteristic value and enables or disables each of the converters belonging to at least one enabled group.

According to another embodiment of the present invention, a method of controlling a plurality of converters for independently converting a voltage of power output from a power source includes receiving at least one predetermined characteristic value of power to be supplied from the power source to a load, determining a number of at least one converter to be enabled from among the plurality of converters based on the received at least one predetermined characteristic value, and outputting signals for controlling the at least one converter among the plurality of converters corresponding to the determined number of the at least one converter.

In an embodiment, the determining the number of the at least one converter to be enabled may include determining the number of the at least one converter to be enabled in proportion to a magnitude of the received at least one predetermined characteristic value.

In an embodiment, the outputting the signals may include outputting signals indicating enabling or disabling of each of the plurality of converters based on the determined number. The outputting may outputting the signals indicating enabling or disabling of each of the plurality of converters and at least one signal for controlling switching of the at least one converter corresponding to the determined number.

In an embodiment, the method may further include determining a duty cycle of the at least one converter corresponding to the determined number, where the outputting the signals further includes outputting signals indicating a switching pattern of the at least one converter corresponding to the determined number based on a determined duty cycle. The method may further include determining sequential switching start points of the at least one converter corresponding to the determined number, where the outputting the signals further includes outputting signals indicating a switching pattern of the at least one converter corresponding to the determined number based on the determined sequential switching start points.

In an embodiment, the outputting the signals further may include outputting signals indicating enabling or disabling of each of converter groups including a group including the plurality of converters and at least one group including a plurality of other converters and signals indicating enabling or disabling of each of the plurality of converters.

According to another embodiment of the present invention, a non-transitory computer-readable storage medium which stores program instructions therein may perform the method when executed by a computer.

### BRIEF DESCRIPTION OF THE DRAWINGS

These and/or other embodiments will become apparent and more readily appreciated from the following description of the embodiments, taken in conjunction with the accompanying drawings in which:

FIG. 1 is a block diagram of an embodiment of a power conversion apparatus according to the present invention;

FIG. 2 is a circuit diagram of an embodiment of any one of direct current to direct current (“DC-DC”) converters included in the power conversion apparatus of FIG. 1, according to the present invention;

FIG. 3 illustrates an operation of an embodiment of the DC-DC converters included in the power conversion apparatus of FIG. 1, according to the present invention;

FIG. 4 is a signal diagram illustrating an embodiment of a switching pattern of the DC-DC converters included in the power conversion apparatus of FIG. 1, according to the present invention;

FIG. 5 is a block diagram of another embodiment of a power conversion apparatus according to the present invention; and

FIG. 6 is a flowchart illustrating an embodiment of a method of controlling DC-DC converters, according to the present invention.

### DETAILED DESCRIPTION

Reference will now be made in detail to embodiments, examples of which are illustrated in the accompanying drawings. In this regard, the present embodiments may have different forms and should not be construed as being limited to the descriptions set forth herein. Accordingly, the embodiments are merely described below, by referring to the figures, to explain embodiments of the present invention. As used herein, expressions such as “at least one of,” when preceding a list of elements, modify the entire list of elements and do not modify the individual elements of the list.

The embodiments of the present invention are characterized by conversion of power output from a power source. Representative examples of the power source are fuel cells, solar cells, batteries, and the like. To prevent the characteristics of the embodiments from being obscured, a detailed description of the well-known matters will be omitted. In an embodiment, a description of peripheral devices of a fuel cell for supplying fuels, air and the like to the fuel cell will be omitted. In general, a fuel cell, a solar cell, and a battery are designed in a stack form in which a plurality of cells is assembled in series or parallel in correspondence with power demanded by a load. Hereinafter, a single cell or a stack in which a plurality of cells are assembled may be simply named as a fuel cell, a solar cell, or a battery. In addition, hereinafter, a direct current may be simply abbreviated to “DC”.

FIG. 1 is a block diagram of a power conversion apparatus 20 according to an embodiment of the present invention. Referring to FIG. 1, the power conversion apparatus 20 may include N direct current to direct current (“DC-DC”) converters 21 (N is a natural number), a battery 22, a measuring instrument 23, and a controller 24. The N DC-DC converters 21 independently convert a voltage of power output from a power source 10 to a voltage according to a control of the controller 24 with respective input terminals thereof connected in parallel to output terminals of the power source 10. In addition, the N DC-DC converters 21 supply the converted power to a load 30 with respective output terminals thereof connected in parallel to the load 30. The battery 22 functions to supplement power output from the N DC-DC converters 21 with input and output terminals thereof connected in parallel to the output terminals of the N DC-DC converters 21. When power consumed by the load 30 is greater than the power output from the N DC-DC converters 21, a shortage portion is supplied from the battery 22 to the load 30. On the contrary, when the power consumed by the load 30 is less than the power output from the N DC-DC converters 21, a surplus portion is stored in the battery 22. In an embodiment, when the power source 10 is a fuel cell, the battery 22 may be used as a start power source of the fuel cell. It will be understood by one of ordinary skill in the art to which the embodiment of FIG. 1 belongs that the embodiment of FIG. 1 may be easily modified and designed in a form in which the battery 22 is removed.

The measuring instrument 23 is connected to input terminals of the load 30 to measure at least one predetermined characteristic value of the power to be supplied from the power source 10 to the load 30. The controller 24 is connected to the measuring instrument 23 to enable or disable each of the N DC-DC converters 21 based on the at least one predetermined characteristic value measured by the measuring instrument 23. In an embodiment, the controller 24 may be implemented by at least one read only memory (“ROM”) in which a program for enabling or disabling each of the N DC-DC converters 21 based on the at least one predetermined characteristic value measured by the measuring instrument 23 is stored, at least one random access memory (“RAM”) for temporarily storing data, at least one processor for executing the program stored in the at least one ROM by using a data storage function of the at least one RAM, and the like.

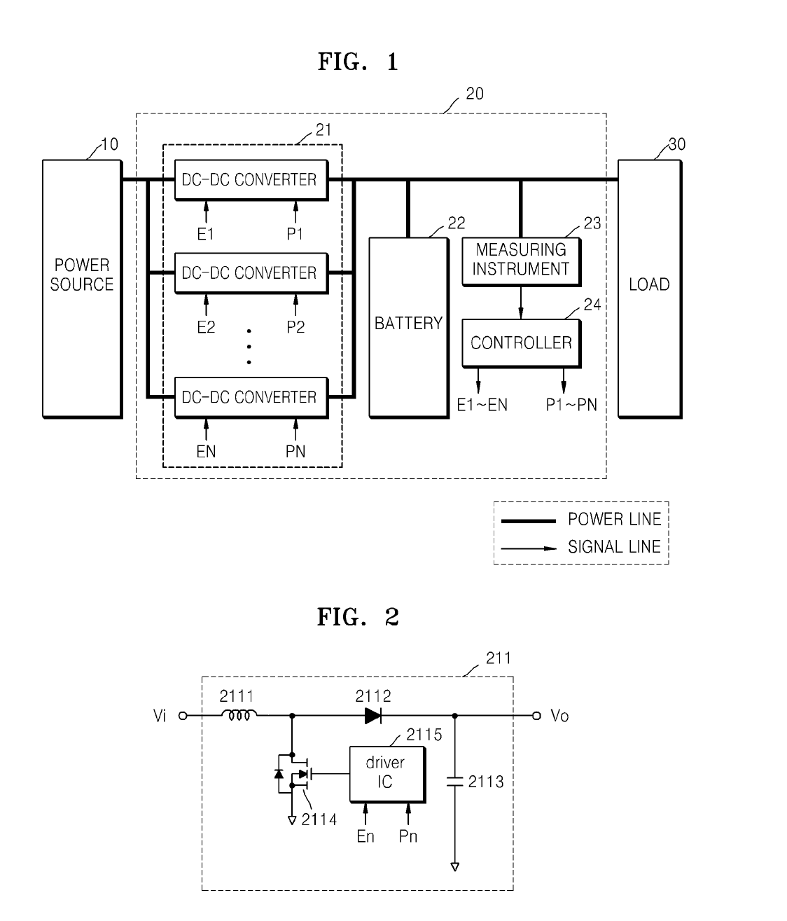

FIG. 2 is a circuit diagram of one DC-DC converter 211 of the DC-DC converters 21 of FIG. 1, according to an embodiment of the present invention. In embodiments, types of a DC-DC converter may be a buck converter for converting a voltage of power output from the power source 10 to a lower voltage, a boost converter for converting a voltage of power output from the power source 10 to a higher voltage, a buck-boost converter for converting a voltage of power output from the power source 10 to a lower or higher voltage, and the like. In the embodiment shown in FIG. 2, the DC-DC converter 211 is a type of the boost converter. Referring to FIG. 2, the DC-DC converter 211 may include an inductor 2111, a diode 2112, a capacitor 2113, a metal oxide semiconductor field effect transistor (“MOSFET”) 2114, and a driver integrated circuit (“IC”) 2115. The MOSFET 2114 is widely used as an electronic switch with a high switching speed and excellent efficiency at a low voltage. However, it will be understood by one of ordinary skill in the art to which the embodiment of FIG. 2 belongs that the embodiment of FIG. 2 may be easily modified and designed by replacing the MOSFET 2114 with another type of a semiconductor having a similar characteristic.

Equation 1 shows a ratio of an input voltage Vi of the DC-DC converter 211 to an output voltage Vo thereof. In Equation 1, a duty cycle D indicates a ratio of a duration in which the MOSFET 2114 is in an on state to a duration in which the MOSFET 2114 is in an off state for one period when the MOSFET 2114 is repeatedly switched in a constant period. When the MOSFET 2114 is continuously in the on state for one period, the duty cycle D is 1, and when the MOSFET 2114 is continuously in the off state for one period, the duty cycle D is 0, for example. As shown in Equation 1, the ratio of the input voltage Vi of the DC-DC converter 211 to the output voltage Vo thereof is determined by the duty cycle D.

$$\frac{{V}_{o}}{{V}_{i}} = \frac{1}{1 - D} \qquad ( 1 )$$

The switching of the MOSFET 2114 is controlled by a drive signal output from the driver IC 2115. The driver IC 2115 is enabled according to a value of a signal En output from the controller 24. In an embodiment, the driver IC 2115 is enabled when a magnitude of the signal En output from the controller 24 is 1 and is disabled when a magnitude of the signal En is 0, for example. That is, the DC-DC converter 211 is enabled when the signal En output from the controller 24 is 1 and is disabled when the signal En is 0. The driver IC 2115 switches the MOSFET 2114 by outputting a drive signal, which corresponds to a value of a signal Pn output from the controller 24, to the MOSFET 2114. That is, the driver IC 2115 converts the Pn signal in a digital form, which is output from the controller 24, to a drive signal in an analog form, which is applicable as an operating voltage of the MOSFET 2114. As described above, in the embodiment of FIG. 1, enabling the DC-DC converter 211 indicates that switching the MOSFET 2114, i.e., switching the DC-DC converter 211, is performed so that power conversion of the DC-DC converter 211 is performed, and disabling the DC-DC converter 211 indicates that switching the MOSFET 2114, i.e., switching the DC-DC converter 211, is not performed so that power conversion of the DC-DC converter 211 is not performed.

As described above, the controller 24 may enable the DC-DC converter 211 by outputting the signal En indicating enabling, e.g., a magnitude of 1, to the DC-DC converter 211 and may switch the DC-DC converter 211 by outputting the signal Pn indicating a switching pattern of the DC-DC converter 211, i.e., the signal Pn indicating a switching pattern of the MOSFET 2114 according to the duty cycle D, to the enabled DC-DC converter 211. In addition, the controller 24 may disable the DC-DC converter 211 by outputting the signal En indicating disabling, e.g., a magnitude of 0, to the DC-DC converter 211. As shown in FIG. 1, the controller 24 enables and disables each of N DC-DC converters 211 and outputs signals E1 to EN and signals P1 to PN to switch at least one enabled DC-DC converter 211.

To prevent a current from being leaked through a disabled DC-DC converter, an electronic switch, such as a MOSFET or the like, may be additionally installed between the output terminals of the power source 10 and the input terminals of each of the N DC-DC converters 21. When a certain DC-DC converter 211 is disabled, the electronic switch is in an off state. In an alternate embodiment, the diode 2112 shown in FIG. 2 may be replaced by the electronic switch, such as a MOSFET or the like. In this case, when the certain DC-DC converter 211 is enabled, the MOSFET replaced from the diode 2112 is in an on state, and when the certain DC-DC converter 211 is disabled, the MOSFET replaced from the diode 2112 is in an off state. Such switching of the additional MOSFET may be controlled by the driver IC 2115.

An existing power conversion apparatus converts a voltage of power output from the power source 10 by using a single DC-DC converter. The single DC-DC converter is designed to be suitable for maximum power consumed by the load 30 not to break the single DC-DC converter in all load range even when a variation range of power consumed by the load 30 is substantially large. In an embodiment, for the single DC-DC converter to be able to accommodate a substantially large current, a thickness of a wire of an inductor of the single DC-DC converter is thick, a magnitude of a capacitor is increased, and a pattern of a printed circuit board (“PCB”) is substantially wide. Accordingly, a space occupied by each of elements of the single DC-DC converter is substantially wide, and as a result, a dead space of the single DC-DC converter is substantially wide. In addition, when a large current flows through the elements of the single DC-DC converter, heat generated by the elements of the single DC-DC converter is substantially high, and a cooling device for cooling the heat is used. Due to these causes, it is difficult to implement a compact DC-DC converter. In particular, when a substantially small current flows through the elements of the single DC-DC converter for a large current, operating efficiency of the elements of the single DC-DC converter for power conversion is very low.

To address these problems, the power conversion apparatus 20 of FIG. 1 employs the N DC-DC converters 21. In the power conversion apparatus 20 of FIG. 1, it is assumed that a magnitude of maximum power which is accommodatable by each of the N DC-DC converters 21 is substantially the same. In an embodiment, it is assumed that each of five DC-DC converters 21 performs voltage conversion of maximum power of 20 milliwatt (mW). In this example, when power of 100 mW is output from the power source 10, the five DC-DC converters 21 may perform voltage conversion by dividing the power of 100 mW into 20 mW each. Since each of the five DC-DC converters 21 may be implemented by elements for voltage conversion of power of 20 mW, a dead space of the DC-DC converters 21 is effectively reduced, and an additional device, such as a cooling device, is not necessary, thereby implementing a compact DC-DC converter.

As described above, the power conversion apparatus 20 of FIG. 1 may operate only DC-DC converters 21 that are necessary for current power to be supplied to the load 30 from among the N DC-DC converters 21 by enabling or disabling each of the N DC-DC converters 21 based on at least one predetermined characteristic value of the power to be supplied from the power source 10 to the load 30. In more detail, the controller 24 may enable at least one DC-DC converter 21, which corresponds to a number proportional to a magnitude of at least one predetermined characteristic value of the power to be supplied to the load 30, from among the N DC-DC converters 21. In the above example, when power of 40 mW is output from the power source 10, if a product of a voltage value and a current value, which are measured by the measuring instrument 23, is 40 mW, the controller 24 may enable two of the five DC-DC converters 21 and disable the remaining three DC-DC converters 21 to maximize power conversion efficiency of each DC-DC converter 21. In the above example, since an existing single 100-mW DC-DC converter processes the power of 40 mW, power conversion efficiency thereof is substantially low. Compared with an operation of two 20-mW DC-DC converters, more power is consumed to operate the 100-mW DC-DC converter.

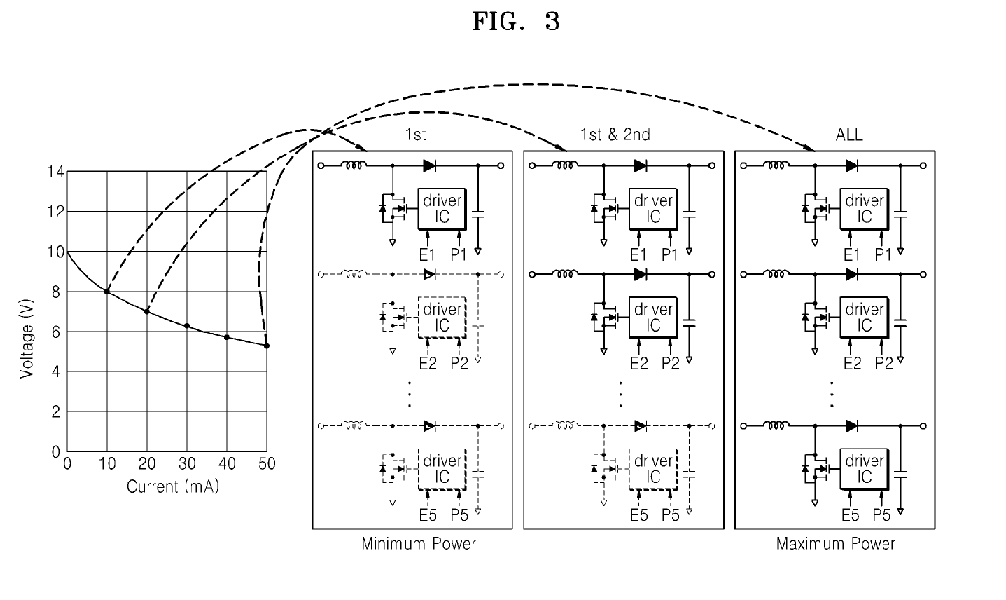

As described in the above example, the controller 24 may enable at least one DC-DC converter 21, which corresponds to a number proportional to a magnitude of a value calculated from a plurality of predetermined characteristic values of the power to be supplied to the load 30, from among the N DC-DC converters 21. That is, the measuring instrument 23 may measure a voltage value and a current value of the power to be supplied to the load 30, and the controller 24 may enable at least one DC-DC converter 211 of the N DC-DC converters 21, which corresponds to a number proportional to a magnitude of a product of the voltage value and the current value measured by the measuring instrument 23, i.e., a magnitude of a power value, from among the N DC-DC converters 21. In an alternative embodiment, the controller 24 may enable at least one DC-DC converter 211 of the N DC-DC converters 21, which corresponds to a number proportional to a magnitude of any one predetermined characteristic value of the power to be supplied to the load 30, from among the N DC-DC converters 21. That is, the measuring instrument 23 may measure a current value of the power to be supplied to the load 30, and the controller 24 may enable at least one DC-DC converter 21, which corresponds to a number proportional to a magnitude of the current value measured by the measuring instrument 23, from among the N DC-DC converters 21. A case where at least one DC-DC converter 21 is enabled according to a current value of the power to be supplied to the load 30 will be described below in detail with reference to FIG. 3.

FIG. 3 illustrates an operation of the DC-DC converters 21 of FIG. 1, according to an embodiment of the present invention. The power conversion apparatus 20 may make a constant current or a constant voltage output from the power source 10 under control of the controller 24. When a constant current is output from the power source 10, a voltage output from the power source 10 varies according to a variation of power output from the power source 10. Likewise, when a constant voltage is output from the power source 10, a current output from the power source 10 varies according to a variation of power output from the power source 10. In an embodiment, when the power source 10 is a fuel cell, to decrease a performance degradation rate according to the use of the fuel cell and plan continuous fuel consumption in the fuel cell, the fuel cell is operated so that a constant current is output from the fuel cell, and this is called a constant current operation of the fuel cell. FIG. 3 illustrates a detailed operation of each of the DC-DC converters 21 in a constant current operation of a fuel cell.

As shown in FIG. 3, due to a characteristic of the fuel cell, a variation range of an output voltage Vo of the fuel cell is not substantially large. Accordingly, a value of a current output from the fuel cell is substantially proportional to a value of power output from the fuel cell. Thus, in the constant current operation of the fuel cell, the value of the power to be supplied from the fuel cell to the load 30 may be estimated from the current value of the power to be supplied from the fuel cell to the load 30. The controller 24 may enable at least one DC-DC converter 21, which corresponds to a number proportional to a magnitude of the current value of the power to be supplied to the load 30, from among the N DC-DC converters 21 and control an operation of the at least one enabled DC-DC converter 21 based on the current value of the power output from the power source 10 so that a constant current is output from the power source 10. Referring to FIG. 3, when a current value measured by the measuring instrument 23 is 10 milliampere (mA), the controller 24 enables a first DC-DC converter 21 from among five DC-DC converters 21 and disables the remaining four DC-DC converters 21, for example. When a current value measured by the measuring instrument 23 is 20 mA, the controller 24 enables first and second DC-DC converters 21 from among the five DC-DC converters 21 and disables the remaining three DC-DC converters 21, for example. When a current value measured by the measuring instrument 23 is 50 mA, the controller 24 enables all of the five DC-DC converters 21, for example.

In more detail, the controller 24 may output a signal Pn indicating a switching pattern of the MOSFET 2114 according to the duty cycle D, which varies according to a variation of the current value of the power output from the power source 10, to the driver IC 2115 of the DC-DC converter 211 so that a constant current is output from the DC-DC converter 211. In an embodiment, when the current value of the power output from the power source 10 decreases, the controller 24 may output a signal Pn indicating a switching pattern of the MOSFET 2114 according to the duty cycle D by which an output voltage Vo of the DC-DC converter 211 increases to the driver IC 2115 of the DC-DC converter 211 in order to increase a current withdrawn by the DC-DC converter 211 from the power source 10. That is, the controller 24 may increase a value of the duty cycle D in proportion to the decrease of the current value of the power output from the power source 10 and output a signal Pn indicating a switching pattern of the MOSFET 2114 according to the increased duty cycle D to the driver IC 2115 of the DC-DC converter 211. When the output voltage Vo of the DC-DC converter 211 increases, a potential difference between the DC-DC converter 211 and the battery 22 increases, thereby resulting in an increase in an amount of a current flowing towards the battery 22 from the power source 10 via the DC-DC converter 211.

On the contrary, when a current value measured by the measuring instrument 23 increases, the controller 24 may output a signal Pn indicating a switching pattern of the MOSFET 2114 according to the duty cycle D by which an output voltage Vo of the DC-DC converter 211 decreases to the driver IC 2115 of the DC-DC converter 211 in order to decrease a current withdrawn by the DC-DC converter 211 from the power source 10. That is, the controller 24 may decrease a value of the duty cycle D in proportion to the increase of the current value of the power output from the power source 10 and output a signal Pn indicating a switching pattern of the MOSFET 2114 according to the decreased duty cycle D to the driver IC 2115 of the DC-DC converter 211. When the output voltage Vo of the DC-DC converter 211 decreases, a potential difference between the DC-DC converter 211 and the battery 22 decreases, thereby resulting in a decrease in an amount of a current flowing towards the battery 22 from the power source 10 via the DC-DC converter 211. Although not shown in FIG. 1, an additional measuring instrument may be connected to the output terminals of the power source 10 to measure a current value of the power output from the power source 10.

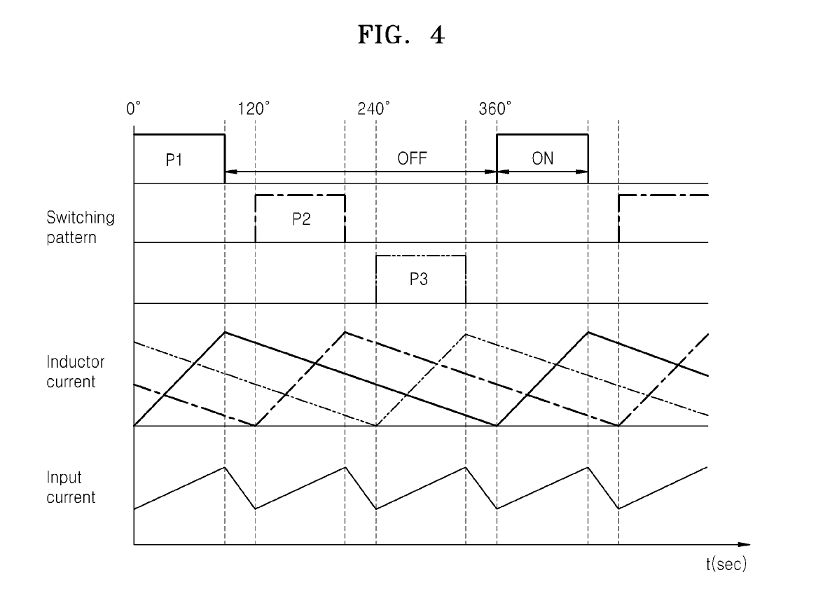

FIG. 4 is a signal diagram illustrating a switching pattern of the N DC-DC converters 21 of FIG. 1, according to an embodiment of the present invention. When enabled DC-DC converters 21 of the N DC-DC converters 21 are simultaneously in an on state or an off state, ripples of a current supplied from the power source 10 to the enabled DC-DC converters 21 are substantially large. In an embodiment, when the power source 10 is a fuel cell, a case where the fuel cell cannot respond to such large current ripples due to the limitation of a fuel amount supplied to the fuel cell may occur. Such a fuel starvation phenomenon of the fuel cell significantly reduces a life span of the fuel cell. To minimize the ripples of the current supplied from the power source 10 to the N DC-DC converters 21, the controller 24 may enable DC-DC converters 21 corresponding to a number proportional to a magnitude of at least one predetermined characteristic value of power to be supplied to the load 30 from among the N DC-DC converters 21 and control an operation of the enabled DC-DC converters 21 so that the enabled DC-DC converters 21 are sequentially switched. FIG. 4 shows an embodiment of a switching pattern in which three enabled DC-DC converters 21 are sequentially switched.

In more detail, referring to FIGS. 1 and 4, the controller 24 outputs a signal P1 for changing an off state of a first DC-DC converter 21 to an on state to the first DC-DC converter 21 of the three enabled DC-DC converters 21, outputs a signal P2 for changing an off state of a second DC-DC converter 21 to an on state to the second DC-DC converter 21 after a predetermined time elapses, and outputs a signal P3 for changing an off state of a third DC-DC converter 21 to an on state to the third DC-DC converter 21 after the predetermined time elapses, for example. As shown in FIG. 4, during a duration in which the DC-DC converter 211 maintains an on state, i.e., during a duration in which the MOSFET 2114 maintains an on state, electrical energy from the power source 10 is accumulated in the inductor 2111 of the DC-DC converter 211, thereby resulting in a gradual increase in a current of the inductor 2111. When the MOSFET 2114 goes from the on state to an off state, the electrical energy accumulated in the inductor 2111 is emitted through the diode 2112, and thus, the current of the inductor 2111 decreases.

Since the input terminals of each of the three DC-DC converters 21 are connected in parallel to the output terminals of the power source 10, a sum of currents of inductors of the three DC-DC converters 21 is an input current of the three DC-DC converters 21, i.e., an output current of the power source 10. When the controller 24 sequentially switches the three enabled DC-DC converters 21 according to the switching pattern shown in FIG. 4, ripples of a current supplied from the power source 10 to the three enabled DC-DC converters 21 decrease. FIG. 4 shows an embodiment in which a certain DC-DC converter changes from an on state to an off state and then a next DC-DC converter changes from an off state to an on state. This may be modified to another embodiment in which the next DC-DC converter changes from an off state to an on state during a duration in which the certain DC-DC converter maintains an on state.

As described above, the controller 24 may determine a switching period of the N DC-DC converters 21 according to the duty cycle D, divides the switching period by the number of DC-DC converters 21 to be enabled, and determine a switching start point of each of the DC-DC converters 21 to be enabled based on the divided durations. As shown in FIG. 4, start points of the divided durations of the switching period of the three DC-DC converters 21 may be the switching start points of the three DC-DC converters 21. An influence according to a variation of the power output from the power source 10 may be minimized by controlling the N DC-DC converters 21 at a substantially high frequency, i.e., shortening a switching period of the N DC-DC converters 21. When the switching period of the N DC-DC converters 21 is shortened, a duration in which a variation of the power output from the power source 10 is maximized is shortened as well, and thus, the influence according to the variation of the power output from the power source 10 is minimized.

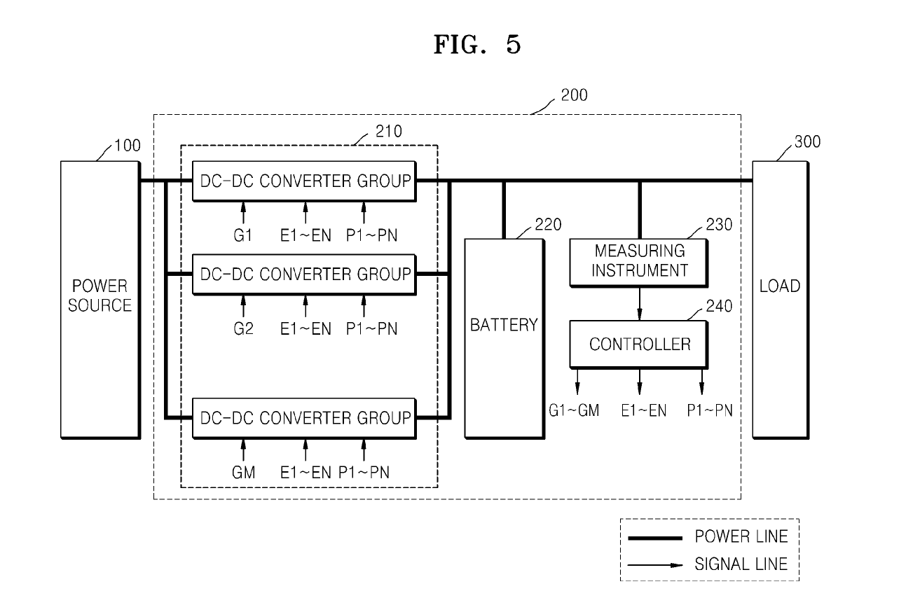

FIG. 5 is a block diagram of a power conversion apparatus 200 according to another embodiment of the present invention. Referring to FIG. 5, the power conversion apparatus 200 may include M DC-DC converter groups 210 (M is a natural number), a battery 220, a measuring instrument 230, and a controller 240. Since the embodiment shown in FIG. 5 is the same as the embodiment shown in FIG. 1 except that the N DC-DC converters 21 shown in FIG. 1 are replaced by the M DC-DC converter groups 210, only a difference between the embodiment shown in FIG. 5 and the embodiment shown in FIG. 1 will be described below. Thus, although omitted hereinafter, the above description related to the embodiment shown in FIG. 1 is also applied to the embodiment to be described below except for the difference.

The power conversion apparatus 200 further includes DC-DC converter groups 210 consisting of a plurality of other DC-DC converters in addition to a group of the N DC-DC converters 21 shown in FIG. 1. Each of the M DC-DC converter groups 210 is configured in the same form as the N DC-DC converters 21 shown in FIG. 1, and DC-DC converters of each of the M DC-DC converter groups 210 independently convert a voltage of power output from a power source 100 to a voltage according to a control of the controller 240 and supply the converted voltage to a load 300. In FIG. 1, the controller 24 may be implemented in a system on chip (“SOC”) form, and since the number of pins of a chip corresponding to the controller 24 is limited, when the number of DC-DC converters 21 shown in FIG. 1 is very large, a case where the controller 24 cannot control all of the DC-DC converters 21 may occur.

In the embodiment shown in FIG. 5, such a problem is solved by grouping DC-DC converters into several groups and controlling the DC-DC converters on a DC-DC converter group basis. The controller 240 individually enables or disables the M DC-DC converter groups 210 on a group basis based on at least one predetermined characteristic value measured by the measuring instrument 230 and individually enables or disables DC-DC converters belonging to at least one enabled DC-DC converter group 210. In an embodiment, it is assumed that each of five DC-DC converter groups 210 includes five DC-DC converters each performing voltage conversion of power of maximum 20 mW, for example. In this example, when power of 320 mW is output from the power source 100, the controller 240 enables four DC-DC converter groups 210 and disables the remaining one DC-DC converter group 210. In addition, the controller 240 enables all DC-DC converters belonging to three of the four enabled DC-DC converter groups 210. In addition, the controller 240 enables one of five DC-DC converters belonging to the remaining one of the four enabled DC-DC converter groups 210 and disables the remaining four DC-DC converters belonging to the remaining one of the four enabled DC-DC converter groups 210.

In more detail, the controller 240 may enable or disable the M DC-DC converter groups 210 on a group basis by respectively outputting signals G1 to GM indicating enabling or disabling on a group basis to the M DC-DC converter groups 210. In addition, the controller 240 may individually enable or disable N DC-DC converters belonging to each enabled DC-DC converter group 210 by outputting signals E1 to EN and signals P1 to PN to each enabled DC-DC converter group 210 and switch at least one enabled DC-DC converter. As shown in FIG. 5, since the controller 240 controls only any one DC-DC converter group 210 at one time, the controller 240 temporarily outputs the signals E1 to EN and the signals P1 to PN to enabled DC-DC converter groups 210 one by one. In an embodiment, each of the M DC-DC converter groups 210 may further include a circuit, e.g., a flip-flop, for maintaining a state according to the temporarily input signals E1 to EN and P1 to PN.

Since each DC-DC converter group 210 includes a plurality of DC-DC converters, a manufacturing cost thereof may be substantially high. In general, electronic devices of the power conversion apparatus 200 shown in FIG. 5 are mounted on a PCB, where a socket for accommodating each DC-DC converter group 210 may be mounted on the PCB instead of directly mounting the electronic devices, such as DC-DC converters, on the PCB. In this case, a user may operate the power conversion apparatus 200 by inserting only DC-DC converters corresponding to a number according to maximum power to be consumed by the load 300 into the socket. Accordingly, since all DC-DC converters do not have to be installed in the power conversion apparatus 200, a manufacturing cost of the power conversion apparatus 200 shown in FIG. 5 may be effectively reduced. Likewise, for the power conversion apparatus 20 shown in FIG. 1, a socket for accommodating individual DC-DC converters 21 may be mounted on a PCB instead of directly mounting electronic devices, such as the DC-DC converters 21, on the PCB.

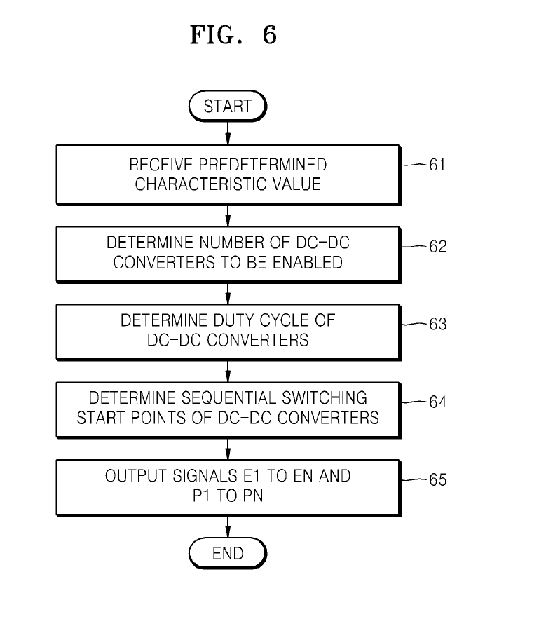

FIG. 6 is a flowchart illustrating a method of controlling DC-DC converters 21, according to an embodiment of the present invention. The method of controlling DC-DC converters 21, which is shown in FIG. 6, includes operations sequentially processed by the controller 24 shown in FIG. 1. Thus, although omitted hereinafter, the above description related to the controller 24 shown in FIG. 1 is also applied to the method of controlling DC-DC converters 21, which is to be described below.

In operation 61, the controller 24 receives at least one predetermined characteristic value of power to be supplied from the power source 10 to the load 30. In operation 62, the controller 24 determines the number of at least one DC-DC converter 21 to be enabled from among the N DC-DC converters 21 based on the at least one predetermined characteristic value received in operation 61. As described above, the controller 24 determines the number of at least one DC-DC converter 21 to be enabled from among the N DC-DC converters 21 in proportional to a magnitude of the at least one predetermined characteristic value received in operation 61. As in the example described above, the controller 24 may determine the number of at least one DC-DC converter 21 to be enabled from among the N DC-DC converters 21 in proportional to a magnitude of a current value of the power to be supplied from the power source 10 to the load 30. In an alternative embodiment, the controller 24 may determine the number of at least one DC-DC converter 21 to be enabled from among the N DC-DC converters 21 in proportional to a magnitude of a product of a voltage value and a current value of the power to be supplied from the power source 10 to the load 30.

According to the example described with reference to FIG. 3, when a current value of the power to be supplied from the power source 10 to the load 30 is 10 mA, the controller 24 determines the number of at least one DC-DC converter 21 to be enabled from among the N DC-DC converters 21 as one. When a current value of the power to be supplied from the power source 10 to the load 30 is 20 mA, the controller 24 determines the number of at least one DC-DC converter 21 to be enabled from among the N DC-DC converters 21 as two. When a current value of the power to be supplied from the power source 10 to the load 30 is 50 mA, the controller 24 determines the number of at least one DC-DC converter 21 to be enabled from among the N DC-DC converters 21 as five. When the value received in operation 61 cannot be directly used to determine the number of at least one DC-DC converter 21 to be enabled, operation of calculating a value to be used to determine the number of at least one DC-DC converter 21 to be enabled from the value received in operation 61 may be added. In an embodiment, operation of multiplying a voltage value of the power to be supplied to the load 30 by a current value thereof may be added.

In operation 63, the controller 24 determines a duty cycle D of the at least one DC-DC converter 21 corresponding to the number determined in operation 62. As described above, the controller 24 may determine a duty cycle D of DC-DC converters 21 based on a current value of the power output from the power source 10. That is, the controller 24 may increase or decrease a value of the duty cycle D in proportional to a variation of the current value of the power output from the power source 10. In operation 64, the controller 24 determines sequential switching start points of the DC-DC converters 21 to operate according to the duty cycle D determined in operation 63. As described above, the controller 24 may determine switching start points of the DC-DC converters 21 by dividing the switching period of the DC-DC converters 21 according to the duty cycle D determined in operation 63 by the number determined in operation 62. In an embodiment, when the number determined in operation 62 is one, i.e., when only one of the N DC-DC converters 21 is enabled, the sequential switching of the N DC-DC converters 21 is impossible, and thus, operation 64 is skipped.

In operation 65, the controller 24 outputs signals for controlling the at least one DC-DC converter 21 corresponding to the number determined in operation 62 based on the results determined in operations 62 to 65. In more detail, the controller 24 generates signals indicating enabling or disabling of corresponding DC-DC converters 21 according to the number determined in operation 62 and outputs the generated signals to the corresponding DC-DC converters 21. In an embodiment, in the example described with reference to FIG. 3, when the number determined in operation 62 is two, signals E1 and E2 indicating enabling of the first and second DC-DC converters 21 are output, and signals E3 to E5 indicating disabling of the third, fourth, and fifth DC-DC converters 21 are output. In addition, the controller 24 generates at least one signal for controlling switching of the at least one DC-DC converter 21 corresponding to the number determined in operation 62 according to the duty cycle D and the switching start points determined in operations 63 and 64 and outputs the generated at least one signal to the at least one DC-DC converter 21 corresponding to the number determined in operation 62.

In an embodiment, when the number determined in operation 62 is one, the controller 24 generates and outputs a signal P1 indicating a switching pattern of one DC-DC converter 21 according to the duty cycle D determined in operation 63. When the number determined in operation 62 is two or more, the controller 24 generates and outputs signals P1 to PN indicating a switching pattern of the N DC-DC converters 21 according to the duty cycle D determined in operation 63 and the switching start points determined in operation 64. According to the embodiment of FIG. 5, signals for individually enabling or disabling the M DC-DC converter groups 210 on a group basis may be output in addition to the signals described above. That is, the controller 24 generates and outputs signals G1 to GM respectively indicating enabling or disabling the M DC-DC converter groups 210 together with the signals E1 to EN and P1 to PN.

As described above, according to the one or more of the above embodiments of the present invention, by employing a plurality of DC-DC converters in a power conversion apparatus for converting power of a power source and supplying the converted power to a load and operating only DC-DC converters necessary for current power to be supplied from the plurality of DC-DC converters to the load according to a variation of power to be supplied from the power source to the load, power conversion efficiency of each DC-Dc converter may be maximized in all load range. In addition, a dead space inside DC-DC converters is effectively reduced, and an additional device, such as a cooling device, is not necessary, thereby implementing a compact DC-DC converter.

In an embodiment, the control method executed by the controller 24 of FIG. 1 or the controller 240 of FIG. 5 can be written as computer programs and can be implemented in general-use digital computers that execute the programs using a computer-readable recording medium. Examples of the computer-readable recording medium include storage media such as magnetic storage media (e.g., ROM, floppy disks, hard disks, etc.) and optical recording media (e.g., CD-ROMs, or DVDs).

In addition, other embodiments of the present invention can also be implemented through computer-readable code and/or instructions in and/or on a medium, e.g., a computer-readable medium, to control at least one processing element to implement any above described embodiment. The medium can correspond to any medium and/or media permitting the storage and/or transmission of the computer-readable code.

The computer-readable code can be recorded/transferred on a medium in a variety of ways, with examples of the medium including recording media, such as magnetic storage media (e.g., ROM, floppy disks, hard disks, etc.) and optical recording media (e.g., CD-ROMs, or DVDs), and transmission media such as Internet transmission media. Thus, the medium may be such a defined and measurable structure including or carrying a signal or information, such as a device carrying a bitstream, for example, according to one or more embodiments of the present invention. The media may also be a distributed network, so that the computer-readable code is stored/transferred and executed in a distributed fashion. Furthermore, the processing element could include a processor or a computer processor, and processing elements may be distributed and/or included in a single device.

While the present invention has been particularly shown and described with reference to embodiments thereof, it will be understood by one of ordinary skill in the art that various changes in form and details may be made therein without departing from the spirit and scope of the present invention as defined by the following claims. The embodiments should be considered in descriptive sense only and not for purposes of limitation. Therefore, the scope of the present invention is defined not by the detailed description of the present invention but by the appended claims, and all differences within the scope will be construed as being included in the present invention.

What is claimed is:

1. A power conversion apparatus comprising:
a plurality of converters which independently converts a voltage of power output from a power source;
a measuring instrument which measures at least one predetermined characteristic value of power to be supplied from the power source to a load; and
a controller for enabling or disabling each of the plurality of converters based on the at least one predetermined characteristic value.

2. The power conversion apparatus of claim 1, wherein the controller enables at least one converter, which corresponds to a number proportional to a magnitude of the at least one predetermined characteristic value of the power to be supplied to the load, from among the plurality of converters.

3. The power conversion apparatus of claim 2, wherein the controller enables at least one converter, which corresponds to a number proportional to a magnitude of any one predetermined characteristic value of the power to be supplied to the load, from among the plurality of converters.

4. The power conversion apparatus of claim 3, wherein
the any one predetermined characteristic value is a current value of the power to be supplied to the load, and
the controller enables or disables each of the plurality of converters based on a magnitude of the current value.

5. The power conversion apparatus of claim 2, wherein the controller enables at least one converter, which corresponds to a number proportional to a magnitude of a value calculated from a plurality of predetermined characteristic values of the power to be supplied to the load, from among the plurality of converters.

6. The power conversion apparatus of claim 5, wherein
the plurality of predetermined characteristic values is a voltage value of the power to be supplied to the load and a current value of the power to be supplied to the load, and
the controller enables at least one converter, which corresponds to a number proportional to a magnitude of a product of the voltage value and the current value, from among the plurality of converters.

7. The power conversion apparatus of claim 1, wherein the controller enables at least one of the plurality of converters based on the at least one predetermined characteristic value and controls an operation of an enabled converter based on a current value of the power output from the power source so that a constant current is output from the power source.

8. The power conversion apparatus of claim 1, wherein the controller enables multiple converters of the plurality of converters based on the at least one predetermined characteristic value and controls operations of the multiple converters so that the enabled multiple converters are sequentially switched.

9. The power conversion apparatus of claim 1, further comprising at least one group including a plurality of other converters different from a group including the plurality of converters,
wherein the controller enables or disables the converter groups on a group basis based on the at least one predetermined characteristic value and enables or disables each of the converters belonging to at least one enabled group.

10. A method of controlling a plurality of converters for independently converting a voltage of power output from a power source, the method comprising:
receiving at least one predetermined characteristic value of power to be supplied from the power source to a load;
determining the number of at least one converter to be enabled from among the plurality of converters based on the received at least one predetermined characteristic value; and
outputting signals for controlling the at least one converter among the plurality of converters corresponding to the determined number of the at least one converter.

11. The method of claim 10, wherein the determining the number of the at least one converter to be enabled comprises determining the number of the at least one converter to be enabled in proportion to a magnitude of the received at least one predetermined characteristic value.

12. The method of claim 10, wherein the outputting the signals comprises outputting signals indicating enabling or disabling of each of the plurality of converters based on the determined number.

13. The method of claim 12, wherein the outputting the signals further comprises outputting the signals indicating enabling or disabling of each of the plurality of converters and at least one signal for controlling switching of the at least one converter corresponding to the determined number.

14. The method of claim 13, further comprising determining a duty cycle of the at least one converter corresponding to the determined number,
wherein the outputting the signals further comprises outputting signals indicating a switching pattern of the at least one converter corresponding to the determined number based on the determined duty cycle of the at least one converter.

15. The method of claim 13, further comprising determining sequential switching start points of the at least one converter corresponding to the determined number,
wherein the outputting the signals further comprises outputting signals indicating a switching pattern of the at least one converter corresponding to the determined number based on the determined sequential switching start points.

16. The method of claim 13, wherein the outputting the signals further comprises outputting signals indicating enabling or disabling of each of converter groups including a group including the plurality of converters and at least one group including a plurality of other converters different from the plurality of converters, and outputting signals indicating enabling or disabling of each of the plurality of converters.

17. A non-transitory computer-readable storage medium which stores program instructions therein to perform a method of controlling a plurality of converters for independently converting a voltage of power output from a power source when executed by a computer, the method comprising:
receiving at least one predetermined characteristic value of the power to be supplied from the power source to a load;
determining the number of at least one converter to be enabled from among the plurality of converters based on the at least one predetermined characteristic value; and
outputting signals for controlling the at least one converter among the plurality of converters corresponding to the number of the at least one converter.
